(19) United States
(12) Patent Application Publication
(10) Pub. No.: US 2022/0340802 A1
(43) Pub. Date: Oct. 27, 2022

(54) RF HEAT DISSIPATION PLASITC AND REPEATER CABINET IMPLEMENTED BY INCLUDING SAME

(71) Applicant: AMOGREENTECH CO., LTD., Gimpo-si, Gyeonggi-do (KR)

(72) Inventor: Jin Hyoung LEE, Gimpo-si, Gyeonggi-do (KR)

(73) Assignee: AMOGREENTECH CO., LTD., Gimpo-si, Gyeonggi-do (KR)

(21) Appl. No.: 17/762,495

(22) PCT Filed: Sep. 16, 2020
(86) PCT No.: PCT/KR2020/012481

§ 371 Date: Mar. 22, 2022

(30) Foreign Application Priority Data
Sep. 23, 2019 (KR) 10-2019-0116586

(51) Int. Cl. C09K 5/14; C08K 7/26; C08K 9/02; H05K 7/20; H04Q 1/02

(52) U.S. Cl. CPC C09K 5/14; C08K 7/26; C08K 9/02; H05K 7/2039; H04Q 1/025; C08K 2201/001; C08K 2201/005

(57) ABSTRACT

Provided is an RF heat dissipation plastic. The heat dissipation plastic according to one embodiment of the present invention is implemented by including: a polymer matrix comprising a base resin; and hollow first fillers dispersed in the polymer matrix. Accordingly, the RF heat dissipation plastic has the advantageous effect of simultaneously exhibiting low permittivity and excellent mechanical strength due to the hollow fillers included therein. In addition, despite the low permittivity and excellent mechanical strength designed for the RF heat dissipation plastic, the RF heat dissipation plastic exhibits excellent heat dissipation performance due to non-hollow fillers included therein, which exhibit heat dissipation performance. According to the present invention, the RF heat dissipation plastic exhibiting the low permittivity and the excellent mechanical strength and heat dissipation performance can minimize performance degradation or functional loss of a repeater cabinet which may be affected by transmission and reception of high-frequency band signals according to permittivity, and thus can be widely applied to various products across all industries.

### CROSS-REFERENCE TO RELATED APPLICATION

This application claims priority to and the benefit of Korean Patent Application No. 10-2019-0116586, filed on Sep. 23, 2019, the disclosure of which is incorporated herein by reference in its entirety.

### TECHNICAL FIELD

The present invention relates to an RF heat dissipation plastic, and more specifically to an RF heat dissipation plastic and a repeater cabinet implemented by including the same.

### BACKGROUND ART

A repeater for mobile communication refers to a device that receives weakened signals in the middle of a communication system, amplifies and retransmits the same, or modulates the waveform of a distorted signal and adjusts or reconstructs the timing and transmits the same. Such a repeater was initially intended for simply retransmitting signals, but recently, it plays the role of a low-cost base station in consideration of service coverage that saves equipment and operating costs.

Meanwhile, the signals transmitted and received through a mobile communication repeater are radio waves, and 5G, which is currently in the process of building networks ahead of commercialization, uses the high frequency bands of 3.5 GHz and 28 GHz, and it uses significantly higher high-frequency bands compared to 4G, and thus, due to the communication characteristics of lower diffraction (strong straightness) and a shorter radio wave reach than 4G, 5G requires the installation of more base stations or repeaters than 4G.

However, as the frequency of electric signals increases, there is a characteristic that the transmission loss increases, and therefore, the development of a material having excellent high-frequency transmission characteristics is an essential factor.

However, in the case of materials with conventional high-frequency transmission characteristics, it was not possible to simultaneously achieve a low dielectric constant and high mechanical strength at a desired level, and there were also technical limitations to expressing excellent heat dissipation performance. As such, the situation is that there is an urgent need to develop a material with high-frequency transmission characteristics which can minimize or prevent signal interference in high-frequency bands and have excellent heat dissipation characteristics while having excellent mechanical strength.

### DISCLOSURE

### Technical Problem

The present invention has been devised in view of the above points, and it is an object of the present invention to provide an RF heat dissipation plastic that can simultaneously exhibit the effects of having a low dielectric constant and excellent mechanical strength.

In addition, it is another object of the present invention to provide an RF heat dissipation plastic that exhibits excellent heat dissipation performance despite being designed to have low dielectric constant and excellent mechanical strength, and a repeater implemented by including the same.

Furthermore, it is still another object of the present invention to provide various products across all industries, such as an RF heat dissipation plastic that can minimize performance degradation or the loss of function of a repeater cabinet that can be affected by the transmission and reception of high-frequency band signals according to the dielectric constant, a repeater implemented by including the same and the like.

### Technical Solution

In order to solve the aforementioned problems, the present invention provides an RF heat dissipation plastic, including a polymer matrix including a base resin; and a hollow first filler dispersed in the polymer matrix.

According to an exemplary embodiment of the present invention, the first filler may have a dielectric constant of 1.2 to 4.8 measured at a frequency of 28 GHz.

In addition, the first filler may include hollow silica.

In addition, the RF heat dissipation plastic may have a dielectric constant of 96% or less compared to a dielectric constant of the polymer matrix measured at a frequency of 28 GHz.

In addition, the first filler may have a hollow average diameter of 0.1 to 33 μm, and an average particle diameter of 0.2 to 35 μm.

In addition, the RF heat dissipation plastic may include 1 to 30 parts by weight of the first filler based on 100 parts by weight of the base resin.

In addition, the base resin may include one compound or two or more compounds or copolymers selected from the group consisting of polycarbonate, polyamide, polyester, polyketone, liquid crystal polymer, polyolefin, polyphenylene sulfide (PPS), polyether ether ketone (PEEK), polyphenylene oxide (PPO), polyether sulfone (PES), polyether imide (PEI), polyimide (PI), polyphthalamide (PPA), polybutylene terephthalate (PBT), acrylonitrile butadiene styrene copolymer resin (ABS), polymethyl methacrylate (PMMA) and polyarylate (PAR).

In addition, the RF heat dissipation plastic may further include a non-hollow second filler dispersed in the polymer matrix.

In addition, the second filler may have an average particle diameter of 5 to 50 μm.

In addition, the second filler may include at least one selected from the group consisting of a non-insulating filler including at least one selected from the group consisting of a carbon-based filler including at least one selected from the group consisting of carbon black, graphite and carbon nanomaterials, a metal-based filler including at least one selected from the group consisting of copper, silver, nickel, gold, platinum and iron, and a non-insulating graphite composite; and an insulating filler including at least one selected from the group consisting of magnesium oxide, yttrium oxide, zirconium oxide, titanium dioxide, aluminum nitride, silicon nitride, boron nitride, aluminum oxide, silica, zinc oxide, barium titanate, strontium titanate, beryllium oxide, manganese oxide, talc, silicon carbide, silicon dioxide, single crystal silicon, and an insulating graphite composite.

In addition, the RF heat dissipation plastic may further include 10 to 60 parts by weight of the second filler based on 100 parts by weight of the base resin.

In addition, the polymer matrix may have a dielectric constant of 2.0 to 4.3 measured at a frequency of 28 GHz, and the RF heat dissipation plastic may have a dielectric constant of 1.3 to 3.7 measured at a frequency of 28 GHz.

In addition, the RF heat dissipation plastic may have a flexural strength of 50% or more compared to a flexural strength of the polymer matrix.

In addition, the base resin may be an amorphous polymer, and the RF heat dissipation plastic may include 1 to 10 parts by weight of the first filler based on 100 parts by weight of the base resin.

In addition, the present invention provides a repeater cabinet having an accommodating part in which a device for relaying an RF signal is accommodated therein, wherein at least a part of the repeater cabinet is the above-described RF heat dissipation plastic.

### Advantageous Effects

According to the present invention, the RF heat dissipation plastic has the advantageous effect of simultaneously exhibiting low permittivity and excellent mechanical strength due to the hollow fillers included therein. In addition, despite the low permittivity and excellent mechanical strength designed for the RF heat dissipation plastic, the RF heat dissipation plastic exhibits excellent heat dissipation performance due to non-hollow fillers included therein, which exhibit heat dissipation performance. According to the present invention, the RF heat dissipation plastic exhibiting the low permittivity and the excellent mechanical strength and heat dissipation performance can minimize performance degradation or functional loss of a repeater cabinet which may be affected by transmission and reception of high-frequency band signals according to permittivity, and thus can be widely applied to various products across all industries.

### DESCRIPTION OF DRAWINGS

FIG. 1 is a cross-sectional view of the RF heat dissipation plastic according to an exemplary embodiment of the present invention.

FIG. 2 is a cross-sectional view of the RF heat dissipation plastic according to another exemplary embodiment of the present invention.

FIG. 3 is an assembled perspective view of a repeater including the repeater cabinet according to an exemplary embodiment of the present invention.

### BEST MODE

Hereinafter, exemplary embodiments of the present invention will be described in detail with reference to the accompanying drawings such that those of ordinary skill in the art to which the present invention pertains can easily practice the present invention. The present invention may be embodied in many different forms and is not limited to the exemplary embodiments described herein. In order to clearly describe the present invention in the drawings, parts that are irrelevant to the description are omitted, and the same reference numerals are assigned to the same or similar components throughout the specification.

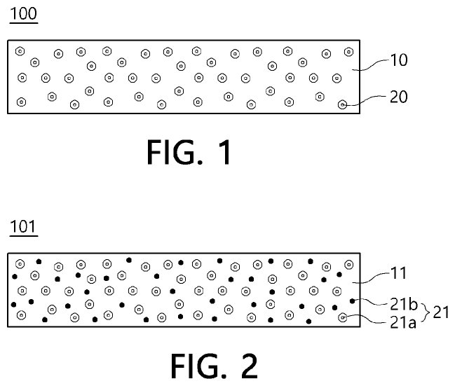

As illustrated in FIG. 1, the RF heat dissipation plastic 100 according to the present invention is implemented by including a polymer matrix 10 including a base resin; and a hollow first filler 20 dispersed in the polymer matrix 10.

First, the polymer matrix 10 will be described.

The polymer matrix 10 is a carrier for holding the first filler 20 to be described below, maintains the shape of the RF heat dissipation plastic, and exhibits an effect of excellent mechanical strength, and the base resin forming the polymer matrix 10 may be used without limitation as long as it is an organic compound commonly used in the art, and preferably, it may be one compound or two or more compounds or copolymers selected from the group consisting of polycarbonate, polyamide, polyester, polyketone, liquid crystal polymer, polyolefin, polyphenylene sulfide (PPS), polyether ether ketone (PEEK), polyphenylene oxide (PPO), polyether sulfone (PES), polyether imide (PEI) and polyimide. The polyamide may be a known polyamide-based compound such as nylon 6, nylon 66, nylon 11, nylon 610, nylon 12, nylon 46, nylon 9T (PA-9T), Qiana, Aramid and the like.

For example, the polyester may be a known polyester-based compound such as polyethylene terephthalate (PET), polytrimethylene terephthalate (IT), polybutylene terephthalate (PBT), polycarbonate and the like.

As another example, the polyolefin may be a known polyolefin-based compound such as polyethylene, polypropylene, polystyrene, polyisobutylene, ethylene vinyl alcohol and the like.

The liquid crystal polymer may be used without limitation in the case of a polymer exhibiting liquid crystallinity in a solution or dissolved state, and since it may be a known type, the present invention does not particularly limit the same.

Meanwhile, since the repeater cabinet to be described below to which the RF heat dissipation plastic is applied must express a predetermined excellent strength, the RF heat dissipation plastic according to an exemplary embodiment of the present invention may use the above-described base resin as the base resin.

Next, the first filler 20 will be described.

The first filler 20 is a hollow filler as described above, and performs a function of reducing the dielectric constant of the RF heat dissipation plastic.

The first filler 20 may be used without limitation, as long as it is a hollow filler that can be commonly used in the art, and preferably, at least one selected from the group consisting of a carbon-based filler, a metal-based filler and a ceramic-based filler may be used, and more preferably, hollow silica may be used.

In addition, the first filler 20 may have a dielectric constant of 1.2 to 4.8, and preferably, 1.5 to 4.5, measured at a frequency of 28 GHz. If the dielectric constant of the first filler measured at a frequency of 28 GHz is less than 1.2, the mechanical strength may be relatively deteriorated, or if a filler having a predetermined heat dissipation characteristic is used, the heat dissipation characteristic may be deteriorated, and if the dielectric constant is more than 4.8, the implemented RF heat dissipation plastic may not express the low dielectric constant at a desired level.

In addition, the first filler 20 may have an average hollow diameter of 0.1 to 33 μm, and preferably, an average hollow diameter of 0.1 to 30 μm. If the average hollow diameter of the first filler is less than 0.1 μm, the implemented RF heat dissipation plastic may not express the low dielectric constant at a desired level, and if the average hollow diameter is more than 33 μm, the mechanical strength may be relatively deteriorated, or when a filler having a predetermined heat dissipation characteristic is used, the heat dissipation characteristic may be deteriorated.

In addition, the first filler 20 may have an average particle diameter of 0.2 to 35 μm, and preferably, an average particle diameter of 0.3 to 33 μm. If the average particle diameter of the first filler is less than 0.2 μm, the mechanical strength may be relatively deteriorated, or when a filler having a predetermined heat dissipation characteristic is used, the heat dissipation characteristic may be deteriorated, and if the average particle diameter is more than 35 μm, the implemented RF heat dissipation plastic may not exhibit the low dielectric constant at a desired level.

In addition, the first filler 20 may be included in an amount of 1 to 30 parts by weight, and preferably, 1 to 25 parts by weight, based on 100 parts by weight of the base resin. If the content of the first filler is less than 1 part by weight based on 100 parts by weight of the base resin, the implemented RF heat dissipation plastic may not express the low dielectric constant at a desired level, and when a filler having a predetermined heat dissipation characteristic is used, the heat dissipation characteristic may be relatively deteriorated, and if it is more than 30 parts by weight, the mechanical strength may be deteriorated.

Meanwhile, according to an exemplary embodiment of the present invention, the base resin may be an amorphous polymer, and preferably, polycarbonate, and in this case, the first filler may be included in an amount of 1 to 10 parts by weight, and preferably, 1 to 8 parts by weight, based on 100 parts by weight of the base resin, which is the amorphous polymer. If the amount of the first filler is less than 1 part by weight based on 100 parts by weight of the base resin, which is the amorphous polymer, the implemented RF heat dissipation plastic may not express the low dielectric constant at a desired level, and when a filler having a predetermined heat dissipation characteristic is used, the heat dissipation characteristic may be relatively deteriorated, and if it is more than 10 parts by weight, the mechanical strength may be relatively deteriorated or cracks may occur.

Meanwhile, as illustrated in FIG. 2, the RF heat dissipation plastic 101 according to another exemplary embodiment of the present invention may include a polymer matrix 11 formed by including a base resin; and a hollow first filler 21a dispersed in the polymer matrix 11, and further include a non-hollow second filler 21b dispersed in the polymer matrix 11.

The second filler 21b performs a function of improving the heat dissipation characteristics of the RF heat dissipation plastic 101.

The second filler 21b may be used without limitation as long as it is a filler that can be conventionally used to improve heat dissipation characteristics in the art, and may preferably include at least one selected from the group consisting of a non-insulating filler including at least one selected from the group consisting of a carbon-based filler including at least one selected from the group consisting of carbon black, graphite and carbon nanomaterials, a metal-based filler including at least one selected from the group consisting of copper, silver, nickel, gold, platinum and iron, and a non-insulating graphite composite; and an insulating filler including at least one selected from the group consisting of magnesium oxide, yttrium oxide, zirconium oxide, titanium dioxide, aluminum nitride, silicon nitride, boron nitride, aluminum oxide, silica, zinc oxide, barium titanate, strontium titanate, beryllium oxide, manganese oxide, talc, silicon carbide, silicon dioxide, single crystal silicon, and an insulating graphite composite.

In addition, the shape of the non-hollow second filler 21b may be a spherical or plate-like granular shape, but since the shape of the second filler may be changed according to the purpose, the present invention does not particularly limit the same.

Meanwhile, the graphite composite may include a graphite composite including graphite, nanoparticles bonded to the surface of the graphite, and a catecholamine layer, and may further include a polymer layer.

The graphite is a mineral in which planar macromolecules in which six-membered rings of carbon atoms are infinitely connected in a plane are stacked in a layered layer, and it may be a known type in the art, and specifically, it may be any one natural graphite of impression graphite, high crystalline graphite and earth graphite, or artificial graphite. When the graphite is natural graphite, for example, it may be expanded graphite obtained by expanding the impression graphite. The artificial graphite may be prepared through a known method. For example, it may be prepared by preparing a thermosetting resin such as polyimide in a film shape of 25 μm or less and graphitizing at a high temperature of 2,500° C. or more to produce single-crystal graphite, or by thermally decomposing hydrocarbons such as methane at a high temperature to prepare highly oriented graphite by chemical vapor deposition (CVD).

In addition, the shape of the graphite may be a known shape, such as a spherical shape, a plate shape, a needle shape or the like, or an atypical shape, and for example, it may be a plate shape. The graphite may be high-purity graphite having a purity of 99% or more, and it may be advantageous in expressing more improved physical properties through the above.

The nanoparticles bound to the surface of the graphite described above function as a medium capable of providing the graphite with a catecholamine layer, which will be described below. When the above is specifically described, as the surface of the graphite described above is hardly provided with functional groups that can mediate chemical reactions, it is not easy to provide a catecholamine layer that can improve the dispersibility of graphite in heterogeneous materials on the surface of the graphite, and there is a problem in that the amount of catecholamine remaining in the actual graphite is very small even if catecholamine is treated with graphite. In addition, in order to solve this problem, there is a limitation to increasing the amount of catecholamine provided on the surface of the modified graphite even if the modification treatment is performed such that the functional groups are provided on the surface of graphite. However, in the case of graphite having nanoparticles on the surface, as catecholamine is easily bonded to the surface of the nanoparticles, there is an advantage that a desired amount of catecholamine may be introduced into the graphite.

When the graphite composite is a non-insulating graphite composite, the nanoparticles may be a metal or a non-metal material that exists as a solid at room temperature, and as non-limiting examples thereof, it may be selected from an alkali metal, an alkaline earth metal, a lanthanum group, an actinium group, a transition metal, a post-transition metal, a metalloid and the like on the periodic table. For example, the nanoparticles may be Ni, Si, Ti, Cr, Mn, Fe, Co, Cu, Sn, In, Pt, Au, Mg and combinations thereof, and it is preferably Cu, Ni or Si.

In addition, when the graphite composite is an insulating graphite composite, the nanoparticles may include at least one selected from the group consisting of magnesium oxide, yttrium oxide, zirconium oxide, titanium dioxide, aluminum nitride, silicon nitride, boron nitride, aluminum oxide, silica, zinc oxide, barium titanate, strontium titanate, beryllium oxide, manganese oxide, talc, silicon carbide, silicon dioxide and single crystal silicon.

Next, the catecholamine layer may be provided at least on the surface of the above-described nanoparticles, thereby improving the excellent fluidity, dispersibility, and interfacial bonding properties between the graphite composite and the polymer compound in the polymer compound of heterogeneous materials to be described below. In addition, the catecholamine layer itself has a reducing power, and at the same time, the amine functional group forms a covalent bond by the Michael addition reaction to the catechol functional group on the surface of the layer, and thus, the secondary surface modification using the catecholamine layer as an adhesive material is possible, and for example, it may act as a bonding material capable of introducing a polymer layer into graphite in order to express more improved dispersibility in the polymer compound.

The catecholamine forming the catecholamine layer is a term that refers to a single molecule having a hydroxy group (—OH) as an ortho-group of a benzene ring, and various alkylamines as a para-group. As non-limiting examples of various derivatives of such a construct, there are dopamine, dopamine-quinone, epinephrine, alpha-methyldopamine, norepinephrine, alpha-methyldopa, droxidopa, indolamine, serotonin, or 5-hydroxydopamine, and as an example, the catecholamine layer may be a dopamine layer.

Meanwhile, a polymer layer may be further coated on the catecholamine layer, and as the compatibility with the base resin forming the RF heat dissipation plastic increases due to the polymer layer, more improved dispersibility and interfacial bonding properties may be implemented. The polymer layer may be the same as or different from the base resin, and specific types may be known.

Meanwhile, the second filler 21b may have an average particle diameter of 5 to 50 μm, and preferably, an average particle diameter of 10 to 40 μm. If the average particle diameter of the second filler is less than 5 μm, detachment such as the heat dissipation filler coming off the surface may occur, the dispersibility may be reduced, and the heat dissipation characteristics may be deteriorated, and if the average particle diameter is more than 50 μm, the surface quality of the RF heat dissipation plastic may be deteriorated, and the mechanical strength may be reduced.

In addition, the second filler 21b may be further included in an amount of 10 to 60 parts by weight, and preferably 20 to 50 parts by weight, based on 100 parts by weight of the base resin. If the amount of the second filler further included is less than 10 parts by weight, based on 100 parts by weight of the base resin, the heat dissipation characteristics may be relatively deteriorated, and if it is more than 60 parts by weight, the surface property of the RF heat dissipation sheet may be deteriorated or the mechanical strength may be lowered.

For the filler 21 having a first filler 21a and a second filler 21b according to an exemplary embodiment of the present invention, the same or different materials may be selectively used as the first filler 21a and the second filler 21b, and thus, the present invention does not particularly limit the same.

Meanwhile, the RF heat dissipation plastic according to an exemplary embodiment of the present invention may be implemented by including, as additives, at least one selected from the group consisting of an antioxidant, an impact improver, a flame retardant, a strength improver, a heat stabilizer, a light stabilizer, a plasticizer, an antistatic agent, a work improver, a UV absorber, a dispersant and a coupling agent.

The antioxidant prevents the main chain of the polymer compound from being broken by shear during extrusion and injection, and is provided to prevent heat discoloration. For the antioxidant, known antioxidants may be used without limitation, and non-limiting examples thereof may include organophosphites such as tris(nonylphenyl)phosphite, tris(2,4-di-t-butylphenyl)phosphite, bis(2,4-di-t-butylphenyl)pentaerythritol diphosphite, distearyl pentaerythritol diphosphite or the like; alkylated monophenols or polyphenols; alkylated reaction products of polyphenols with diene, such as tetrakis[methylene(3,5-di-tert-butyl-4-hydroxyhydrocinnamate)] methane, or the like; butylated reaction products of para-cresol or dicyclopentadiene; alkylated hydroquinone; hydroxylated thiodiphenyl ether; alkylidene-bisphenol; benzyl compounds; esters of monohydric or polyhydric alcohols and beta-(3,5-di-tert-butyl-4-hydroxyphenyl)-propionic acid; esters of monohydric or polyhydric alcohols and beta-(5-tert-butyl-4-hydroxy-3-methylphenyl)-propionic acid; esters of thioalkyl or thioaryl compounds such as distearylthiopropionate, dilaurylthiopropionate, ditridecylthiopropionate, octadecyl-3-(3,5-di-tert-butyl-1-4-hydroxyphenyl)propionate, pentaerythrityl-tetrakis [3-(3,5-di-tert-butyl-4-hydroxyphenyl)propionate or the like; and amides of beta-(3,5-di-tert-butyl-4-hydroxyphenyl)-propionic acid or the like, or mixtures thereof. The antioxidant may be provided in an amount of 0.01 to 0.5 parts by weight based on 100 parts by weight of the base resin.

The impact modifier may be used without limitation in the case of a known component capable of improving the impact resistance by expressing the flexibility and stress relaxation properties of a composite material, and for example, at least one component selected from the group consisting of thermoplastic polyurethane (TPU), thermoplastic polyolefin (TPO), maleic acid-grafted EPDM, core/shell structured elastic particles, rubber-based resins and polyamide-based materials may be provided as the impact modifier. The thermoplastic polyolefin is a group of materials similar to rubber, and it may be a linear polyolefin block copolymer having a polyolefin block such as polypropylene, polyethylene and the like and a rubber block, or a blend of polypropylene and ethylene-propylene-diene monomer (EPDM), which is an ethylene-based elastomer. In addition, since a known thermoplastic polyolefin may be used, the description of a specific type thereof will be omitted in the present invention. In addition, since a known thermoplastic polyurethane may be used, the description of a specific type thereof will be omitted. In addition, for the elastic particles of the core/shell structure, for example, an allyl-based resin may be used for the core, and for the shell portion, it may be a polymer resin having a functional group capable of reacting to increase compatibility and bonding strength with the base resin.

The flame retardant may include, for example, halogenated flame retardants, like tetrabromo bisphenol A oligomers such as BC58 and BC52, brominated polystyrene or poly(dibromo-styrene), brominated epoxy, decabromodiphenylene oxide, pentabromobenzyl acrylate monomer, pentabromobenzyl acrylate polymer, ethylene-bis(tetrabromophthalimide, bis(pentabromobenzyl)ethane and metal hydroxides such as Mg(OH)₂ and Al(OH)₃, melamine cyanurate, phosphor-based FR systems such as red phosphorus, melamine polyphosphate, phosphate ester, metal phosphinate, ammonium polyphosphate, expandable graphite, sodium or potassium perfluorobutane sulfate, sodium or potassium perfluorooctane sulfate, sodium or potassium diphenylsulfonate and sodium- or potassium-2,4,6,-trichlorobenzoate and N-(p-tolylsulfophonyl)-p-toluenesulfimide potassium salt, N—(N′-benzylaminocarbonyl) sulfanylimide potassium salt, or a mixture thereof, but is not limited thereto. The flame retardant may be included in an amount of 0.1 to 50 parts by weight based on 100 parts by weight of the base resin.

The strength improver may be used without limitation in the case of a known component capable of improving the strength of a composite material, and as non-limiting examples thereof, at least one component selected from the group consisting of glass fiber, glass beads, zirconium oxide, wollastonite, gibbsite, boehmite, magnesium aluminate, dolomite, calcium carbonate, magnesium carbonate, mica, talc, silicon carbide, kaolin, calcium sulfate, barium sulfate, silicon dioxide, ammonium hydroxide, magnesium hydroxide and aluminum hydroxide may be included as the strength improver. For example, the strength improver may be glass fiber. The strength improver may be included in an amount of 5 to 35 parts by weight, preferably 15 to 35 parts by weight, and more preferably 25 to 33.3 parts by weight, based on 100 parts by weight of the base resin.

Meanwhile, when a glass fiber is used as the strength improver, the glass fiber may have a length of 2 to 8 mm, preferably 2 to 7 mm, and most preferably, 4 mm, and it may have an average fiber diameter of 1 to 30 μm, preferably, 3 to 20 μm, and most preferably, 10 μm.

In addition, the heat stabilizer may be used without limitation in the case of a known heat stabilizer, and non-limiting examples thereof include organophosphites such as triphenyl phosphite, tris-(2,6-dimethylphenyl)phosphite, tris-(mixed mono- and di-nonylphenyl)phosphate or the like; phosphates such as dimethylbenzene phosphonate or the like, trimethyl phosphate, or the like, or mixtures thereof. The heat stabilizer may be included in an amount of 0.01 to 0.5 parts by weight based on 100 parts by weight of the base resin.

In addition, the light stabilizer may be used without limitation in the case of a known light stabilizer, and non-limiting examples thereof may include benzotriazoles such as 2-(2-hydroxy-5-methylphenyl)benzotriazole, 2-(2-hydroxy-5-tert-octylphenyl)-benzotriazole and 2-hydroxy-4-n-octoxy benzophenone or the like, or mixtures thereof.

In addition, the plasticizer may be used without limitation in the case of a known plasticizer, and non-limiting examples thereof may include dioctyl-4,5-epoxy-hexahydrophthalate, tris-(octoxycarbonylethyl)isocyanurate, phthalic esters such as tristearin, epoxidized soybean oil or the like, or mixtures thereof. The plasticizer may be included in an amount of 0.5 to 3.0 parts by weight based on 100 parts by weight of the base resin.

In addition, as the antistatic agent, a known antistatic agent may be used without limitation, and non-limiting examples thereof may include glycerol monostearate, sodium stearyl sulfonate, sodium dodecylbenzenesulfonate, polyether block amides, or mixtures thereof, which may be commercially obtained from, for example, BASF under the trade name Irgastat; Alkema under the trade name PEBAX; Sanyo Chemical industries under the trade name Pelestat. The antistatic agent may be included in an amount of 0.1 to 1.0 parts by weight based on 100 parts by weight of the base resin.

In addition, as the work improver, a known work improver may be used without limitation, and non-limiting examples thereof may include metal stearate, stearyl stearate, pentaerythritol tetrastearate, beeswax, montan wax, paraffin wax, polyethylene wax or the like, or mixtures thereof. The work improver may be included in an amount of 0.1 to 1.0 parts by weight based on 100 parts by weight of the base resin.

In addition, as the UV absorber, a known UV absorber may be used without limitation, and non-limiting examples thereof include hydroxybenzophenone; hydroxybenzotriazole; hydroxybenzotriazine; cyanoacrylate; oxanilides; benzoxazinones; 2-(2H-benzotriazol-2-yl)-4-(1,1,3,3,-tetramethylbutyl)-phenol; 2-hydroxy-4-n-octyloxybenzophenone; 2-[4,6-bis(2,4-dimethylphenyl)-1,3,5-triazine-2-yl]-5-(octyloxy)-phenol; 2,2′-(1,4-phenylene)bis(4H-3,1-benzoxazine-4-one); 1,3-bis[(2-cyano-3,3-diphenylacryloyl)oxy]-2,2-bis[[(2-cyano-3,3-biphenylacryloyl)oxy]methyl]propane; 2,2′-(1,4-phenylene)bis(4H-3,1-benzoxazine-4-one); 1,3-bis[(2-cyano-3,3-diphenylacryloyl)oxy]-2,2-bis[[(2-cyano-3,3-diphenylacryloyl)oxy]methyl]propane; nano-sized inorganic materials such as titanium oxide, cerium oxide and zinc oxide having a particle diameter of less than 100 nm; or the like, or mixtures thereof. The UV absorber may be included in an amount of 0.01 to 3.0 parts by weight based on 100 parts by weight of the base resin.

In addition, as the dispersant and the coupling agent, a known dispersant and a coupling agent may be used without limitation, and as non-limiting examples of the coupling agent, maleic acid-grafted polypropylene, a silane-based coupling agent and the like may be used for heat resistance.

Meanwhile, the RF heat dissipation plastics 100, 101 according to the present invention may have a dielectric constant of 96% or less, and preferably, 95.6% or less measured at a frequency of 28 GHz, compared to the dielectric constant of the polymer matrices 10, 11 measured at a frequency of 28 GHz.

In addition, the RF heat dissipation plastics 100, 101 according to the present invention may have a flexural strength of 50% or more, preferably 60% or more, and more preferably, 70% or more, based on the flexural strength of the polymer matrices 10, 11.

As the RF heat dissipation plastics 100, 101 of the present invention satisfy the dielectric constant ratio and mechanical strength ranges of the polymer matrices 10, 11, it is possible to simultaneously exhibit the effects of having a low dielectric constant, excellent mechanical strength and excellent heat dissipation characteristics.

In addition, the polymer matrices 10, 11 may have a dielectric constant of 2.0 to 4.3, and preferably, a dielectric constant of 2.2 to 4.0 measured at a frequency of 28 GHz, and the RF heat dissipation plastics 100, 101 may have a dielectric constant of 1.3 to 3.7, and preferably, a dielectric constant of 1.5 to 3.5 measured at a frequency of 28 GHz.

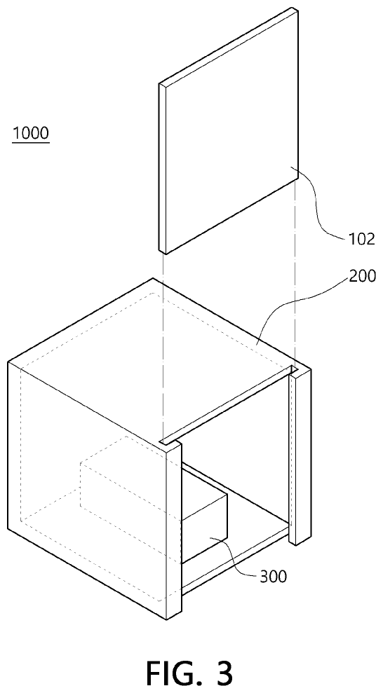

Meanwhile, as illustrated in FIG. 3, the present invention may be implemented as a repeater cabinet having an accommodating part in which a repeater 300 including a device for relaying an RF signal is accommodated therein, wherein at least a part of the repeater cabinet is the above-described RF heat dissipation plastic 102.

The RF heat dissipation plastic 102 may be implemented as at least a part or all of the repeater cabinet, and as illustrated in FIG. 3, when implemented as at least a part, it may be composed of the first part which is the RF heat dissipation plastic 102 and the second part which is other parts.

In this case, since the second part 200 may be a known material used as a repeater cabinet, the present invention does not particularly limit the same.

In addition, when the RF heat dissipation plastic 102 is implemented as all of the repeater cabinet, the first part which is the RF heat dissipation plastic 102 and the second part 200 may be implemented with the same material.

Meanwhile, the relay unit 300 may be an electronic device provided in a known repeater, and for example, it may be a front-end unit (FEU), a quad base radio (QBR), a router/SRI (site reference interface), a channel service unit (CSU), an optical terminal device, a rectifier or the like.

In addition, the repeater 1000 may further include a heat sink (not illustrated) or a fan (not illustrated) inside or outside the repeater cabinet to dissipate heat generated inside the repeater.

Meanwhile, the repeater 1000 may further include other configurations that may be further provided in a known repeater in addition to the above-described configurations, and the present invention does not particularly limit the same.

### MODES OF THE INVENTION

The present invention will be described in more detail through the following examples, but the following examples are not intended to limit the scope of the present invention, and these examples should be construed to aid the understanding of the present invention.

<Preparation Example: Preparation of Second Filler>

First, in order to prepare a second filler provided in a polymer matrix, graphite with nickel (Ni) nanoparticles formed on the surface at 23° C. and in an atmospheric state was immersed in a coating composition in which dopamine at a concentration of 2 mM, 13 parts by weight of sodium periodate (Na₂S₂O₈) as an oxidizing agent and 20 parts by weigh of a buffer solution (Tris-base, Fisher) based on 100 parts by weight of dopamine were mixed in a solvent containing 65% by weight of pure water (DI water) and 35% by weight of methanol, and after stirring for 2.5 hours, it was filtered and washed with DI water and dried at 23° C. to form a catecholamine layer on the surface of graphite to prepare a graphite composite.

### Example 1: Manufacture of RF Heat Dissipation Plastic

Based on 100 parts by weight of PA6 as a base resin, 15 parts by weight of hollow silica having a hollow average diameter of 15 μm and an average particle diameter of 17 μm as a first filler and 35 parts by weight of the graphite composite having an average particle diameter of 25 μm prepared according to the preparation example above as a second filler were mixed, and by compounding the same using a 48-pi twin-screw extruder, an RF heat dissipating plastic as shown in FIG. 2 was manufactured.

### Examples 2 to 18 and Comparative Examples 1 to 2

RF heat dissipation plastics as shown in Tables 1 to 4 were manufactured in the same manner as in Example 1, except that the average hollow diameter, average particle diameter, content and inclusion of the first filler, and the average particle diameter, content and inclusion of the second filler were changed.

### Experimental Example

The following physical properties were evaluated for each of the RF heat dissipation plastics manufactured according to the examples and comparative examples, and the results are shown in Tables 1 to 4.

1. Evaluation of Heat Dissipation Performance

In order to prevent external influences, performance evaluation was conducted in a sealed chamber measuring 30 cm×30 cm×30 cm in width, length and height, respectively. Specifically, a planar heating element was attached to the RF heat dissipation plastic, and heat was generated by applying a current of 350 mA, and after holding for 60 minutes, the temperature of the planar heating element was measured to evaluate the heat dissipation performance.

In this case, a high measurement temperature means poor heat dissipation performance, and a low measurement temperature means excellent heat dissipation performance.

In addition, based on the measurement temperature of Example 1 as 100, the measurement temperatures for the rest of the examples and comparative examples were shown as relative percentages.

2. Evaluation of Mechanical Strength

The flexural strengths of the RF heat dissipation plastics were evaluated using a universal tensile tester (Utm).

In this case, based on the flexural strength of Example 1 as 100, the flexural strengths of the other examples and comparative examples were shown as relative percentages.

3. Evaluation of Dielectric Constant and Dielectric Loss

For each RF heat dissipation plastic, the dielectric constant and dielectric loss were measured in the gigahertz (GHz) region through a resonant cavity by using a network analyzer (E8364A (45 MHz to 50 GHz), Agilent Technologies).

4. Evaluation of Surface Quality

For the RF heat dissipation plastics according to the examples and comparative examples, it was confirmed whether there was a bumpy or rough feeling by touching the surface with a hand in order to check the surface quality. When there was a smooth feeling, it was assigned 5, and when the area of the rough feeling was 2% or less of the total outer surface of the RF heat dissipation plastic, it was assigned 4, and when the area was more than 2% and 5% or less, it was assigned 3, and when the area was more than 5% and 10% or less, it was assigned 2, and when the area was more than 10% and 20% or less, it was assigned 1, and when the area was more than 20%, it was assigned 0.

TABLE 1

| Classification | | Example 1 | Example 2 | Example 3 | Example 4 | Example 5 |
|---|---|---|---|---|---|---|
| First filler | Average diameter of | 15 | 0.05 | 0.5 | 28 | 35 |
| | hollow (μm) | | | | | |
| | Average particle | 17 | 0.1 | 1 | 31 | 38 |
| | diameter (μm) | | | | | |
| | Content (parts by | 15 | 15 | 15 | 15 | 15 |
| | weight) | | | | | |
| Second | Average particle | 25 | 25 | 25 | 25 | 25 |
| filler | diameter (μm) | | | | | |
| | Content (parts by | 35 | 35 | 35 | 35 | 35 |
| | weight) | | | | | |

| | | | | | |
|---|---|---|---|---|---|
| Evaluation of heat dissipation | 100 | 122 | 103 | 105 | 126 |
| performance | | | | | |
| Evaluation of flexural strength | 100 | 77 | 98 | 97 | 75 |
| Dielectric constant (@28 GHz) | 3.09 | 3.34 | 3.13 | 3.11 | 3.30 |
| Dielectric loss (@28 GHz) | 0.015 | 0.032 | 0.016 | 0.015 | 0.029 |
| Surface quality | 5 | 4 | 5 | 5 | 5 |

TABLE 2

| Classification | | Example 6 | Example 7 | Example 8 | Example 9 | Example 10 |
|---|---|---|---|---|---|---|
| First filler | Average diameter of | 15 | 15 | 15 | 15 | 15 |
| | hollow (μm) | | | | | |
| | Average particle | 17 | 17 | 17 | 17 | 17 |
| | diameter (μm) | | | | | |
| | Content (parts by | 0.5 | 2 | 23 | 35 | 15 |
| | weight) | | | | | |
| Second | Average particle | 25 | 25 | 25 | 25 | 3 |
| filler | diameter (μm) | | | | | |
| | Content (parts by | 35 | 35 | 35 | 35 | 35 |
| | weight) | | | | | |

| | | | | | |
|---|---|---|---|---|---|
| Evaluation of heat dissipation | 130 | 109 | 100 | 99 | 125 |
| performance | | | | | |
| Evaluation of flexural strength | 104 | 103 | 96 | 71 | 97 |
| Dielectric constant (@28 GHz) | 3.42 | 3.15 | 3.08 | 3.08 | 3.11 |
| Dielectric loss (@28 GHz) | 0.034 | 0.020 | 0.015 | 0.015 | 0.020 |
| Surface quality | 5 | 5 | 5 | 4 | 5 |

TABLE 3

| | | Example | Example | Example | Example | Example |
|---|---|---|---|---|---|---|
| Classification | | 11 | 12 | 13 | 14 | 15 |
| First filler | Average diameter of | 15 | 15 | 15 | 15 | 15 |
| | hollow (μm)) | | | | | |
| | Average particle | 17 | 17 | 17 | 17 | 17 |
| | diameter (μm) | | | | | |
| | Content (parts by | 15 | 15 | 15 | 15 | 15 |
| | weight) | | | | | |
| Second | Average particle | 10 | 40 | 60 | 25 | 25 |
| filler | diameter (μm) | | | | | |
| | Content (parts by | 35 | 35 | 35 | 5 | 20 |
| | weight) | | | | | |

| | | | | | |
|---|---|---|---|---|---|
| Evaluation of heat dissipation | 106 | 100 | 100 | 136 | 109 |
| performance | | | | | |
| Evaluation of flexural strength | 99 | 98 | 72 | 102 | 101 |
| Dielectric constant (@28 GHz) | 3.10 | 3.10 | 3.11 | 3.11 | 3.10 |
| Dielectric loss (@28 GHz) | 0.016 | 0.015 | 0.016 | 0.015 | 0.015 |
| Surface quality | 5 | 5 | 2 | 5 | 5 |

TABLE 4

| | | Example | Example | Example | Comparative | Comparative |
|---|---|---|---|---|---|---|
| Classification | | 16 | 17 | 18 | Example 1 | Example 2 |
| First filler | Average diameter of | 15 | 15 | 15 | — | — |
| | hollow (μm) | | | | | |
| | Average particle | 17 | 17 | 17 | — | — |
| | diameter (μm) | | | | | |
| | Content (parts by | 15 | 15 | 15 | — | — |
| | weight) | | | | | |
| Second | Average particle | 25 | 25 | — | 25 | — |
| filler | diameter (μm) | | | | | |
| | Content (parts by | 50 | 70 | — | 35 | — |
| | weight) | | | | | |

| | | | | | |
|---|---|---|---|---|---|
| Evaluation of heat dissipation | 98 | 95 | 140 | 116 | 145 |
| performance | | | | | |
| Evaluation of flexural strength | 95 | 68 | 105 | 105 | 108 |
| Dielectric constant (@28 GHz) | 3.09 | 3.10 | 3.13 | 3.48 | 3.5 |
| Dielectric loss (@28 GHz) | 0.015 | 0.015 | 0.016 | 0.0041 | 0.042 |
| Surface quality | 5 | 1 | 5 | 5 | 5 |

As can be seen from Tables 1 to 4, Examples 1, 3, 4, 7, 8, 11, 12, 15 and 16, which satisfied all of the average hollow diameter, average particle diameter, content and inclusion of the first filler, and the average particle diameter, content and inclusion of the second filler according to the present invention, simultaneously exhibited all of the excellent heat dissipation performance, mechanical strength and surface quality and the effects of remarkably low dielectric constant and dielectric loss, compared to Examples 2, 5, 6, 9, 10, 13, 14, 17, 18 and Comparative Examples 1 to 2, in which any one of the above was omitted.

Although an exemplary embodiment of the present invention has been described above, the spirit of the present invention is not limited to the exemplary embodiment presented in the present specification, and those skilled in the art who understand the spirit of the present invention will be able to easily suggest other exemplary embodiments by modifying, changing, deleting or adding components within the scope of the same spirit, but this is also said to be within the scope of the present invention.

1. An RF heat dissipation plastic, comprising:
a polymer matrix comprising a base resin; and
a hollow first filler dispersed in the polymer matrix.

2. The RF heat dissipation plastic of claim 1, wherein the first filler has a dielectric constant of 1.2 to 4.8 measured at a frequency of 28 GHz.

3. The RF heat dissipation plastic of claim 1, wherein the first filler comprises hollow silica.

4. The RF heat dissipation plastic of claim 1, wherein the RF heat dissipation plastic has a dielectric constant of 96% or less compared to a dielectric constant of the polymer matrix measured at a frequency of 28 GHz.

5. The RF heat dissipation plastic of claim 1, wherein the first filler has a hollow average diameter of 0.1 to 33 μm, and an average particle diameter of 0.2 to 35 μm.

6. The RF heat dissipation plastic of claim 1, wherein the RF heat dissipation plastic comprises 1 to 30 parts by weight of the first filler based on 100 parts by weight of the base resin.

7. The RF heat dissipation plastic of claim 1, wherein the base resin comprises one compound or two or more compounds or copolymers selected from the group consisting of polycarbonate, polyamide, polyester, polyketone, liquid crystal polymer, polyolefin, polyphenylene sulfide (PPS), polyether ether ketone (PEEK), polyphenylene oxide (PPO), polyether sulfone (PES), polyether imide (PEI), polyimide (PI), polyphthalamide (PPA), polybutylene terephthalate (PBT), acrylonitrile butadiene styrene copolymer resin (ABS), polymethyl methacrylate (PMMA) and polyarylate (PAR).

8. The RF heat dissipation plastic of claim 1, further comprising a non-hollow second filler dispersed in the polymer matrix.

9. The RF heat dissipation plastic of claim 8, wherein the second filler has an average particle diameter of 5 to 50 μm.

10. The RF heat dissipation plastic of claim 8, wherein the second filler comprises at least one selected from the group consisting of a non-insulating filler comprising at least one selected from the group consisting of a carbon-based filler comprising at least one selected from the group consisting of carbon black, graphite and carbon nanomaterials, a metal-based filler comprising at least one selected from the group consisting of copper, silver, nickel, gold, platinum and iron, and a non-insulating graphite composite; and
an insulating filler comprising at least one selected from the group consisting of magnesium oxide, yttrium oxide, zirconium oxide, titanium dioxide, aluminum nitride, silicon nitride, boron nitride, aluminum oxide, silica, zinc oxide, barium titanate, strontium titanate, beryllium oxide, manganese oxide, talc, silicon carbide, silicon dioxide, single crystal silicon, and an insulating graphite composite.

11. The RF heat dissipation plastic of claim 8, further comprising 10 to 60 parts by weight of the second filler based on 100 parts by weight of the base resin.

12. The RF heat dissipation plastic of claim 1, wherein the polymer matrix has a dielectric constant of 2.0 to 4.3 measured at a frequency of 28 GHz, and
wherein the RF heat dissipation plastic has a dielectric constant of 1.3 to 3.7 measured at a frequency of 28 GHz.

13. The RF heat dissipation plastic of claim 1, wherein the RF heat dissipation plastic has a flexural strength of 50% or more compared to a flexural strength of the polymer matrix.

14. The RF heat dissipation plastic of claim 1, wherein the base resin is an amorphous polymer, and
wherein the RF heat dissipation plastic comprises 1 to 10 parts by weight of the first filler based on 100 parts by weight of the base resin.

15. A repeater cabinet having an accommodating part in which a device for relaying an RF signal is accommodated therein,
wherein at least a part of the repeater cabinet is the RF heat dissipation plastic according to claim 1.
